(19) United States
(12) Patent Application Publication
(10) Pub. No.: US 2026/0311959 A1
(43) Pub. Date: Oct. 8, 2026

(54) SYSTEMS AND METHODS FOR SUBVOXEL SEM BASED VOLUME ELECTRON MICROSCOPY

(71) Applicant: Yale University, New Haven, CT (US)

(72) Inventors: C. Shan Xu, Woodbridge, CT (US); Song Pang, Woodbridge, CT (US)

(73) Assignee: Yale University, New Haven, CT (US)

(21) Appl. No.: 19/485,521

(22) PCT Filed: May 16, 2024
(86) PCT No.: PCT/US2024/029700

§ 371 Date: Nov. 18, 2025

Related U.S. Application Data
(60) Provisional application No. 63/503,396, filed on May 19, 2023.

(51) Int. Cl. H01J 37/244; H01J 37/28

(52) U.S. Cl. CPC H01J 37/244; H01J 37/28; H01J 2237/24507

(57) ABSTRACT

A scanning electron microscopy (SEM) system performs subvoxel microscopy with a probe and detector. The probe directs incoming probe electrons at a sample with an energy and a direction. The detector detects electrons scattered by the sample and generates a two-dimensional energy profile map of the detected electrons. The system may determine subvoxel information including features of the sample smaller than a size of the probe using the energy and direction and the two-dimensional energy profile map. The system may determine three-dimensional subvoxel information of the sample. The system may be a focused ion beam scanning electron microscopy (FIB-SEM) system with an emitter directing a FIB at the sample to separate layers thereof. For each of multiple layers, the system may obtain the energy and direction and generate the two-dimensional energy profile map. The system may generate three-dimensional subvoxel volume information of the sample thicker than individual layers.

### CROSS-REFERENCE TO RELATED APPLICATIONS

This application claims the benefit under 35 USC 119(e) of U.S. application Ser. No. 63/503,396, filed May 19, 2023, under attorney docker number Y0087.70164US00, and titled “SYSTEMS AND METHODS FOR SUBVOXEL SEM BASED VOLUME ELECTRON MICROSCOPY”, which is hereby incorporated herein by reference in its entirety.

### BACKGROUND

Scanning electron microscopy (SEM) may be used for imaging in biological and other environments. Conventional SEM has a resolution limit that has persisted for 80 years, limited by a size of scanning electron probes.

### SUMMARY

According to aspects of the disclosure, there is provided an apparatus, comprising a scanning electron microscopy (SEM) system, comprising a probe configured to direct incoming probe electrons at a sample, the incoming probe electrons having an energy and a direction, and a detector configured to detect electrons scattered by the sample and generate a two-dimensional energy profile map of the detected electrons.

In some embodiments, the two-dimensional energy profile map of the detected electrons comprises a map having at least two spatial dimensions (e.g., a first spatial dimension and a second spatial dimension) and, for a plurality of points in the map, a two-dimensional energy profile comprising an electron count along a first profile dimension and an electron energy along a second profile dimension.

In some embodiments, the detector is further configured to detect energy and direction of the detected electrons and generate the two-dimensional energy profile map of the detected electrons based on the detected energy and direction of the detected electrons.

In some embodiments, the SEM system is further configured to determine subvoxel information of the sample using the energy of the incoming probe electrons, the direction of the incoming probe electrons, and the two-dimensional energy profile map of the detected electrons.

In some embodiments, the subvoxel information comprises features of the sample that are smaller than a size of the probe.

In some embodiments, the SEM system is further configured to determine three-dimensional subvoxel information of the sample.

In some embodiments, the SEM system is a focused ion beam scanning electron microscopy (FIB-SEM) system comprising an emitter configured to direct a FIB at the sample and separate layers of the sample using the FIB.

In some embodiments, FIB-SEM system is further configured to for a first layer of the sample having a sample layer thickness, obtain energy and direction of incoming probe electrons and generate a two-dimensional energy profile map of detected electrons, using the FIB, separate the first layer of the sample from a second layer of the sample, for the second layer of the sample, obtain energy and direction of incoming probe electrons and generate a two-dimensional energy profile map of detected electrons, and generate three-dimensional subvoxel volume information of the sample, the three-dimensional subvoxel volume information having a volume information thickness greater than the sample layer thickness.

In some embodiments, the detector is further configured to, for each of the first layer and the second layer, detect the energy and direction of the detected electrons and generate the two-dimensional energy profile map of the detected electrons based on the detected energy and direction of the detected electrons.

In some embodiments, the detector comprises a three-dimensional detection surface. In some embodiments, the detector comprises a concave detection surface. In some embodiments, the detector comprises a partial sphere detection surface. In some embodiments, the detector comprises a hemisphere detection surface.

In some embodiments, the detector comprises at least one planar detection surface. In some embodiments, the detector comprises a single planar detection surface. In some embodiments, the detector comprises a circular detection surface. In some embodiments, the detector comprises a plurality of planar detection surfaces.

In some embodiments, the detector comprises three or more planar detection surfaces and the three or more planar detection surfaces are arranged around an axis of the probe and normals of the three or more planar detection surfaces are angled relative to the axis. In some embodiments, the three or more planar detection surfaces comprises four planar detection surfaces arranged in respective quadrants around the axis.

In some embodiments, the detector further comprises a gap and the probe is configured to direct incoming probe electrons at the sample through the gap. In some embodiments, a detection surface of the detector comprises an opening and the probe is configured to direct incoming probe electrons at the sample through the opening.

According to aspects of the disclosure, there is provided a method of determining subvoxel information for use with a scanning electron microscopy (SEM) system, the method comprising obtaining an energy of incoming probe electrons and a direction of the incoming probe electrons, obtaining a two-dimensional energy profile map of detected electrons, and determining subvoxel information of a sample using the energy of incoming probe electrons, the direction of the incoming probe electrons, and the two-dimensional energy profile map of the detected electrons.

In some embodiments, obtaining the two-dimensional energy profile map of the detected electrons comprises obtaining a map having at least two spatial dimensions (e.g., a first spatial dimension and a second spatial dimension) and, for a plurality of points in the map, obtaining a two-dimensional energy profile comprising an electron count along a first profile dimension and an electron energy along a second profile dimension.

In some embodiments, the method further comprises detecting energy and direction of the detected electrons and generating the two-dimensional energy profile map of the detected electrons based on the detected energy and direction of the detected electrons.

In some embodiments, the method further comprises determining subvoxel information of the sample using the energy of the incoming probe electrons, the direction of the incoming probe electrons, and the two-dimensional energy profile map of the detected electrons.

In some embodiments, the subvoxel information comprises features of the sample that are smaller than a size of a probe of the SEM system.

In some embodiments, the method further comprises determining three-dimensional subvoxel information of the sample.

In some embodiments, the method further comprises separating layers of the sample.

In some embodiments, the method further comprises, for a first layer of the sample having a sample thickness, obtaining energy and direction of incoming probe electrons and generating a two-dimensional energy profile map of detected electrons, separating the first layer of the sample from a second layer of the sample, for the second layer of the sample, obtaining energy and direction of incoming probe electrons and generating a two-dimensional energy profile map of detected electrons, and generating three-dimensional subvoxel volume information of the sample, the three-dimensional subvoxel volume information having a volume information thickness greater than the sample layer thickness.

In some embodiments, the method further comprises, for each of the first layer and the second layer, detecting the energy and direction of the detected electrons and generating the two-dimensional energy profile map of the detected electrons based on the detected energy and direction of the detected electrons.

According to aspects of the disclosure, there is provided at least one non-transitory computer-readable storage medium having instructions encoded thereon that, when executed by at least one processor, cause the at least one processor to perform a method of determining subvoxel information for use with a scanning electron microscopy (SEM) system, the method comprising obtaining an energy of incoming probe electrons and a direction of the incoming probe electrons, obtaining a two-dimensional energy profile map of detected electrons, and determining subvoxel information of a sample using the energy of the incoming probe electrons, the direction of the incoming probe electrons, and the two-dimensional energy profile map of the detected electrons.

In some embodiments, obtaining the two-dimensional energy profile map of the detected electrons comprises obtaining a map having at least two spatial dimensions (e.g., a first spatial dimension and a second spatial dimension) and, for a plurality of points in the map, obtaining a two-dimensional energy profile comprising an electron count along a first profile dimension and an electron energy along a second profile dimension.

In some embodiments, the method further comprises detecting energy and direction of the detected electrons and generating the two-dimensional energy profile map of the detected electrons based on the detected energy and direction of the detected electrons.

In some embodiments, the method further comprises determining subvoxel information of the sample using the energy of the incoming probe electrons, the direction of the incoming probe electrons, and the two-dimensional energy profile map of the detected electrons.

In some embodiments, the subvoxel information comprises features of the sample that are smaller than a size of a probe of the SEM system.

In some embodiments, the method further comprises determining three-dimensional subvoxel information of the sample.

In some embodiments, the method further comprises separating layers of the sample.

In some embodiments, the method further comprises, for a first layer of the sample having a sample layer thickness, obtaining energy and direction of incoming probe electrons and generating a two-dimensional energy profile map of detected electrons, separating the first layer of the sample from a second layer of the sample, for the second layer of the sample, obtaining energy and direction of incoming probe electrons and generating a two-dimensional energy profile map of detected electrons, and generating three-dimensional subvoxel volume information of the sample, the three-dimensional subvoxel volume information having a volume information thickness greater than the sample layer thickness.

In some embodiments, the method further comprises, for each of the first layer and the second layer, detecting the energy and direction of the detected electrons and generating the two-dimensional energy profile map of the detected electrons based on the detected energy and direction of the detected electrons.

### BRIEF DESCRIPTION OF DRAWINGS

FIGS. 1A-1B show an exemplary embodiment of a scanning electron microscopy (SEM) system;

FIG. 2 shows an exemplary embodiment of an operating space of an SEM system;

FIG. 3 shows an exemplary block diagram of a special purpose computer system that can be improved over conventional implementations based on implementations and/or execution of methods discussed herein;

FIG. 4 shows an exemplary process flow of a method of determining subvoxel information for use with a SEM system;

FIG. 5A shows a first exemplary embodiment of a detector of an SEM system;

FIG. 5B shows a second exemplary embodiment of a detector of an SEM system;

FIG. 5C shows a third exemplary embodiment of a detector of an SEM system;

FIG. 6 shows an exemplary SEM system voxel and subvoxels thereof;

FIG. 7A shows a first exemplary sample for an SEM system;

FIG. 7B shows first exemplary data of a SEM system for the sample of FIG. 7A;

FIG. 8A shows a second exemplary sample for an SEM system;

FIG. 8B shows second exemplary data of a SEM system for the sample of FIG. 8A;

FIG. 9A shows a third exemplary sample for an SEM system;

FIG. 9B shows third exemplary data of a SEM system for the sample of FIG. 9A;

FIG. 10A shows a fourth exemplary sample for an SEM system;

FIG. 10B shows fourth exemplary data of a SEM system for the sample of FIG. 10A;

FIG. 11A shows a fifth exemplary sample for an SEM system;

FIG. 11B shows fifth exemplary data of a SEM system for the sample of FIG. 11A;

FIG. 12A shows a sixth exemplary sample for an SEM system;

FIG. 12B shows sixth exemplary data of a SEM system for the sample of FIG. 12A;

FIG. 13A shows a seventh exemplary sample for an SEM system;

FIG. 13B shows seventh exemplary data of a SEM system for the sample of FIG. 13A;

FIG. 14A shows an eighth exemplary sample for an SEM system; and

FIG. 14B shows eight exemplary data of a SEM system for the sample of FIG. 14A.

### DETAILED DESCRIPTION

A scanning electron microscopy (SEM) system performs subvoxel microscopy with a probe and detector. The probe directs incoming probe electrons at a sample with an energy and a direction. The detector detects electrons scattered by the sample and generates a two-dimensional energy profile map of the detected electrons. The system may determine subvoxel information including features of the sample smaller than a size of the probe using the energy and direction and the two-dimensional energy profile map. The system may determine three-dimensional subvoxel information of the sample. The system may be a focused ion beam scanning electron microscopy (FIB-SEM) system with an emitter directing a FIB at the sample to separate layers thereof. For each of multiple layers, the system may obtain the energy and direction and generate the two-dimensional energy profile map. The system may generate three-dimensional subvoxel volume information of the sample thicker than individual layers.

Provided is a scanning electron microscopy (SEM) system configured to transcend a resolution limit of conventional SEM systems that has persisted for 80 years. In conventional SEM systems, resolution may be one order of magnitude worse than that of transmission electron microscopy (TEM) systems, and may generally be limited by the scanning electron probe diameter. Conventional SEM architectures for image formation involves scanning the surface pixel-by-pixel and only counting the backscattered and/or secondary electrons. When pixel size is smaller than the probe size, the electron counts obtained from adjacent pixels leads to oversampling without substantial additional information. As such, electron probe diameter provides a limit of conventional SEM resolution. Conventional approaches for reducing probe size have focused on aberration mitigation by attempting to improve electron source and lens design. However, smaller conventional probes may induce larger diffraction errors worsen resolution. Accordingly, some conventional practical SEM systems may only provide resolution capped at 1-2 nm on gold on carbon calibration specimens, and 4 nm on block face biological specimens.

SEM systems described herein provide image resolution higher than conventional SEM system resolution limit. SEM systems according to the disclosure have a new architecture for forming SEM images. According to aspects of the disclosure, SEM systems may treat an SEM scanning electron probe as an illumination source with a controllable profile and record a solid angle and energy of each electron to form a two-dimensional electron energy map. A resulting two-dimensional electron energy profile may encode a combination of features in X, Y and Z directions that are smaller than a probe size of the system. This map may further have a distinctive signature pattern reflecting the unique scattering events of individual electrons. The SEM system may then use the available electron properties to mathematically reconstruct subvoxel biomolecule or other structures that are finer than the size of the electron probe.

Aspects of the disclosure provide a novel SEM detector configured to captures the two-dimensional electron energy map with high efficiency.

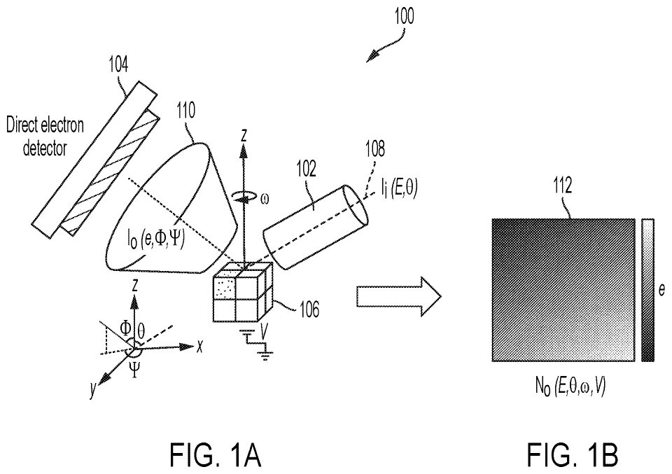

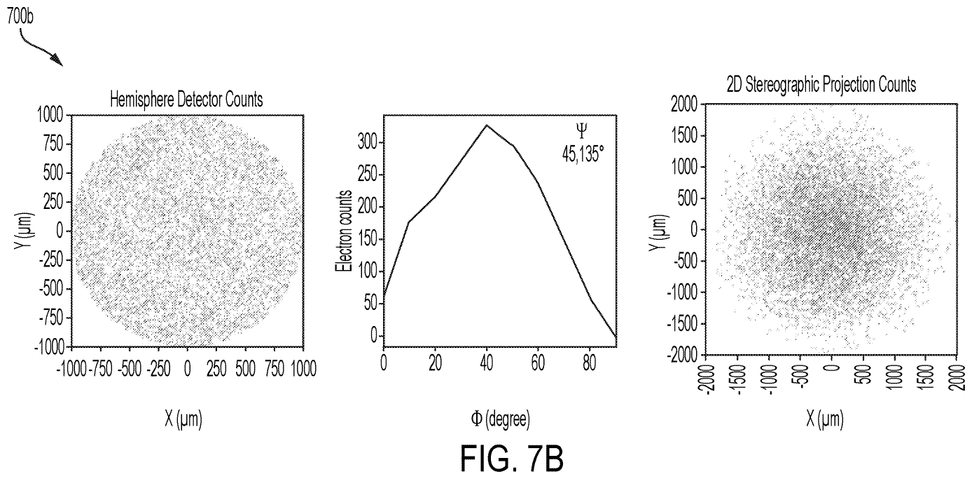

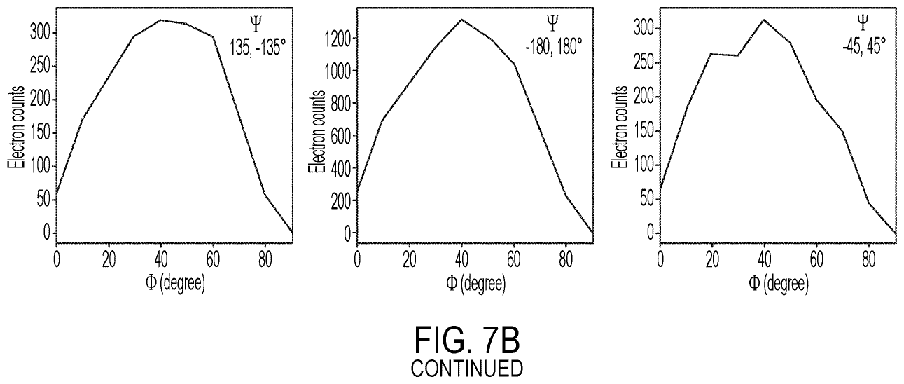

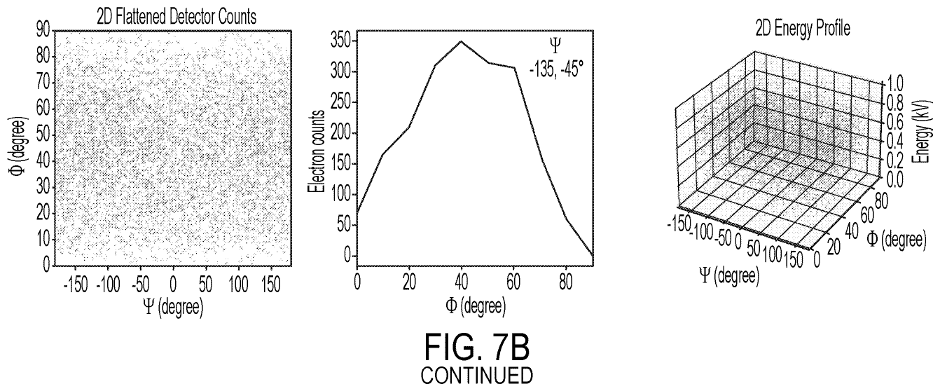

Referring now to FIG. 1A, an exemplary embodiment of an SEM system 100 is provided. SEM system 100 comprises a probe 102 and a detector 104. SEM system may be configured to image a sample 106. The probe 102 may be configured to direct incoming probe electrons 108 at the sample 106. As further discuss below, the incoming probe electrons 108 may have an energy and a direction. The detector 104 may be configured to detect electrons 110 scattered by the sample. The detector 104 may further be configured to generate a two-dimensional (or otherwise multi-dimensional) energy profile map 112, illustrated in FIG. 1B, using the detected electrons. In some embodiments, two-dimensional electron information of two-dimensional energy profile map 112 may be electron information from one or more of FIGS. 7B, 8B, 9B, 10B, 11B, 12B, 13B, and 14B (discussed in more detail below), or other electron information.

FIG. 1A illustrates one exemplary embodiment of incoming electrons Iᵢ and resulting scattered electrons Iₒ. Incoming probe electrons Iᵢ may have an energy of E and incident angle of θ relative to a z-axis. Further, scattered electrons Io may have energy e (e<=E) with a direction defined by φ and ψ. In some embodiments, the SEM system 100 derives a direction of scattered electrons 110 (e.g., φ and ψ) from spatial location of pixels of the detector 104, relative to the sample 106, for example, as shown in FIG. 1A. Additionally, a voltage bias of V is applied to the specimen or sample. For a given structure, resulting scattered electrons form specific angular and energy distributions which may be functions of E, θ, and V. A two-dimensional electron energy profile may encode a combination of features in X, Y and Z directions that are smaller than a probe size and have a distinctive signature pattern reflecting unique scattering events of individual electrons. In some embodiments, a specimen can rotate around z axis at an angle of ω to produce a reflection tomography.

According to some embodiments, a direct electron detector may be used to detect an electron energy profile, No (E, θ, ω, V). In some embodiments, TEM cameras may be used to generate a two-dimensional mapping of electrons. For example, a TEM detector may have an acquisition rate of about 5,000 frames per second (fps). In some embodiments, a TEM detector may not measure energy. Accordingly, aspects of the disclosure provide an SEM system configured to perform an energy filtering scheme to capture energy measurements. An acquisition rate of the SEM system may in some embodiments be substantially improved by reducing a number of pixels. Such a detector may be included in a subvoxel SEM system.

SEM systems described herein may obtain electron information for multiple layers of a sample, which may be used in order to generate three-dimensional subvoxel information for the sample. For example, the SEM system may measure a sample layer each having a sample layer thickness to obtain energy and direction of incoming probe electrons and generate a two-dimensional energy profile map of detected electrons, before using a FIB to separate the layer from another layer of the sample, which may in turn be measured to obtain the energy and direction of incoming probe electrons and generate a two-dimensional energy profile map of detected electrons for that other layer. The SEM system may then generate three-dimensional subvoxel volume information of the sample, with the vertical dimension of the three-dimensional subvoxel volume being greater than the thickness of a single sample layer. If multiple layers are measured, the vertical dimension of the three-dimensional subvoxel volume may be equal to the thickness of the multiple layers.

Aspects of the disclosure relate to a physics and mathematical model configured to reconstruct subvoxel structure.

In various embodiments, SEM system may obtain a two-dimensional electron energy map and use that to recover subvoxel information with an inverse scattering function. For example, formation of a two-dimensional electron energy map may be considered as a forward transformation of incident electrons scattered by subvoxel structures of a specimen. The forward model and the inverse scattering function are optimized through iterative progression with experimental data. In some embodiments, a library is generated and provided based on simulation and then refined through experimental measurements. The library may be used to speed up the subvoxel features prediction based on the electron energy profiles. In various embodiments, the system is configured to use artificial intelligence, including one or more trained statistical models, to enhance the accuracy of inverse scattering functions and models.

For example, the system may use both an improved or optimized forward model and an improved or optimized inverse scattering function. The improved or optimized models may be obtained using AI-based training, for example, by training a statistical model using training datasets. Use of the trained statistical models may improve the overall performance of the inverse scattering function.

Aspects of the disclosure relate to subvoxel SEM architecture that transcends conventional SEM system resolution limit that has persisted since the birth of SEM system 80 years ago.

In some embodiments, an SEM system's detector's pixel number, energy detection resolution, and spatial arrangement relative to the specimen and electron column are improved or optimized to enable a more or most efficient detection of electron energy profiles, which are used to reconstruct subvoxels. In some embodiments the reconstruction model constructed based on a configuration of a detector, and the model is tuned based on configuration of the detector's pixel number, energy detection resolution, and spatial arrangement relative to the specimen and electron column, or other properties. The detector and reconstruction model are included in the SEM system and provide a subvoxel SEM system configured to image with a higher resolution than allowed by conventional SEM probe size in the last 80 years.

Aspects of the disclosure relate to subvoxel FIB-SEM.

In some embodiments, subvoxel SEM systems described herein are integrated with a focused ion beam to provide a subvoxel FIB-SEM system. In some embodiments, subvoxel FIB-SEM systems may image specimen with near-atomic resolution for whole cell imaging. Conventional systems do not provide near-atomic resolution for whole cell imaging. Accordingly, SEM systems described herein may bridge a resolution and imageable volume gap between conventional imaging schema such as cryo-ET and enhanced FIB-SEM.

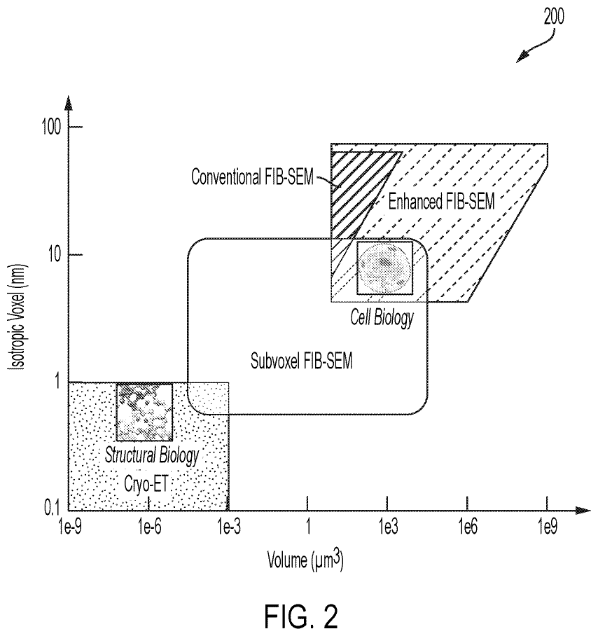

FIG. 2 shows an exemplary embodiment of SEM system in an operating space 200. The operating space 200 is defined by isotropic voxel resolution (on the y-axis) and imaging volume (on the x-axis). As illustrated in FIG. 2, subvoxel FIB-SEM systems described herein bridge the fields of structural biology and cell biology. FIG. 2 shows an operating environment of exemplary subvoxel FIB-SEM systems. This operating environment connects the fields of structural biology and cell biology by bridging a resolution and image volume gap of cryo-ET and enhanced FIB-SEM. Accordingly, SEM systems described herein may probe structure and function across scales from protein domains to proteins to organelles to cells, in an isolated form, but also in native tissue environments and within the holistic milieu of whole cells.

Aspects of the disclosure relate to subvoxel volume SEM.

According to some embodiments, SEM systems further provide an expanded subvoxel SEM architecture integrated with other volume electron microscopy technologies. These SEM systems substantially expand a horizon of other conventional volume SEM technologies, such as serial block face SEM and serial section SEM, and other imagine schema, to provide resolutions higher than the resolution limits of these conventional imaging schema, thus providing a profound impact on biology.

Aspects of the disclosure provide the following improvements over conventional systems.

First, there is provided a novel SEM detector that is configured to record angular and energy distributions of scattered electrons. A resulting two-dimensional electron energy profile encodes a combination of features in X, Y and Z directions that are smaller than a probe size of an SEM system and has a distinctive signature pattern that reflects unique scattering events of individual electrons.

Second, there is provided a mathematical and physical model configured to have inputted the above-described novel electron properties to reconstruct and output subvoxel structures having finer resolution than the size of the electron probe.

Third, there is provided subvoxel SEM systems that image with a higher resolution than conventional SEM resolution limits that have persisted since the birth of conventional SEM systems 80 years ago. The subvoxel SEM systems provided herein image with resolution beyond the electron probe diameter by collecting electron information of additional dimensions, followed by reconstruction of subvoxel features that are smaller than the electron probe size.

Fourth, there is provided subvoxel FIB-SEM systems. A subvoxel SEM system described herein is integrated with a focused ion beam, to provide a subvoxel FIB-SEM system configured to image specimens with near-atomic resolution for whole cell imaging.

Fifth, there is provided subvoxel volume SEM systems. A subvoxel SEM system described herein may be integrated with volume electron microscopy systems. The subvoxel volume SEM systems described herein provide expanded volume SEM technologies, such as serial block face SEM and serial section SEM, and other imaging schema, thereby providing imaging at resolutions higher than the resolution limits of those conventional imaging schema.

Using SEM systems described herein, resolution of SEM systems is no longer constrained by electron probe size, which has been the fundamental limit since the birth of SEM systems 80 years ago. SEM systems described herein thus provide functional improvements to all existing SEM technologies and associated platforms. Conventional SEM systems do not reach the resolutions described herein. The SEM systems described herein provided super resolution SEM that provides broad impact on life science, materials research, semiconductor manufactory, and other applications.

Aspects of the disclosure relate to public health, providing an advance in understanding of how cells and tissues function and of what causes diseases. SEM systems described herein transcend the resolution limit of conventional SEM that has persisted for 80 years. The disclosure provides subvoxel FIB-SEM reaching near-atomic resolution for whole cell imaging. In some embodiments, SEM systems described herein may be deployed broadly in the field of electron microscopy, providing discoveries in biology, physiology, pathology, and other fields. In some embodiments the SEM systems described herein provide for discovery of new aspects of structural bases of disease and provide new perspectives on therapeutic development.

SEM systems described herein provide for viewing of biomolecules in cells and measuring changes in biomolecule and cell structure, quantity, distribution, and interactions, which is fundamental to understanding biology. In contrast, conventional cryo-electron tomography (cryo-ET) systems may visualize protein molecules at near-atomic resolution within cellular context but is limited to a fraction of whole cell volume.

Aspects of the disclosure relate to enhanced focused ion beam scanning electron microscopy (FIB-SEM) systems. Enhanced FIB-SEM systems provide powerful biology discovery platforms. For example, enhanced FIB-SEM systems may provide expanded maximum image volume, (for example, expanded by five orders of magnitude) which provides advanced system architecture configured to provide a finest possible isotropic resolution of 4 nm for whole cell imaging. FIB-SEM systems are configured to generate large and detailed brain connectome, and may provide open-access, three-dimensional atlases of whole cells and tissues with 4-nm voxels. Such FIB-SEM systems provide numerous transformational discoveries in life science. However, such 4-nm isotropic resolution may fall short of robust visualization of 3D ultrastructure of sub-10 nm features. A fundamental barrier of conventional SEM systems is related to conventional SEM system architecture, which may cap SEM system resolution based on a diameter of a scanning electron probe of the SEM system.

As described above, the SEM systems described herein transcend the conventional SEM system resolution limits that have persisted for 80 years. Furthermore, SEM systems described herein may be combined a focused ion beam (FIB). Such a combined system provides subvoxel FIB-SEM configured to generate near-atomic resolution for whole cell imaging. Conventional systems do not provide near-atomic resolution for whole cell imaging. Accordingly, the SEM systems provided herein bridge fields that are currently not connected: structural biology and cell biology, by providing a probing architecture that is configured to image across scales from protein to organelle to cell, within native tissue environments.

Aspects of the disclosure also provide subvoxel FIB-SEM systems. Such FIB-SEM systems may be configured to provide new high-resolution large volume EM, which may reveal new structure-function relationships in biology. As described above, electron angular and energy distributions may encode subvoxel features in X, Y and Z that are smaller than the probe size. According to aspects of the disclosure, SEM architectures are provided that exploit comprehensive electron properties, and use physics and mathematical models to reconstruct subvoxel information that is encoded in said electron angular and energy distributions. Conventional systems and approaches do not exploit the subvoxel information that is encoded in said electron angular and energy distributions. In contrast, some conventional systems may instead focus on highly stable FIB-SEM architectures with high effective reliability at the fine isotropic resolutions, such as 4 nm.

As discussed above, the systems here in provide subvoxel FIB-SEM functionality as a novel technological approach that bridges the resolution and volume gap between conventional imaging schema, such as cryo-ET and FIB-SEM. SEM systems configured for whole cell mapping at near-atomic resolutions may be applied to technical fields such as EM, physiology, cell biology, and structural biology, and provide illumination to vistas in life science and therapeutic development that are inaccessible with conventional imaging systems.

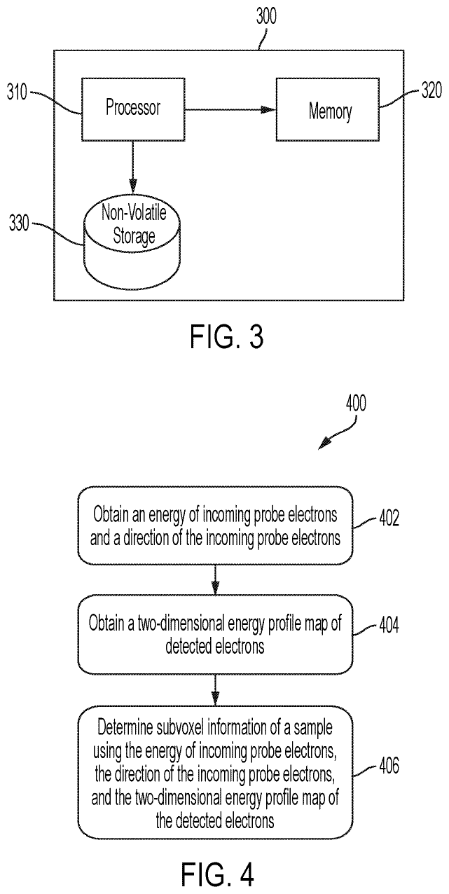

An illustrative implementation of a computer system 300 that may be used in connection with any of the embodiments of the disclosure provided herein is shown in FIG. 3. The computer system 300 may include one or more processors 310 and one or more articles of manufacture that comprise non-transitory computer-readable storage media (e.g., memory 320 and one or more non-volatile storage media 330). The processor 310 may control writing data to and reading data from the memory 320 and the non-volatile storage device 330 in any suitable manner. To perform any of the functionality described herein, the processor 310 may execute one or more processor-executable instructions stored in one or more non-transitory computer-readable storage media (e.g., the memory 320), which may serve as non-transitory computer-readable storage media storing processor-executable instructions for execution by the processor 310.

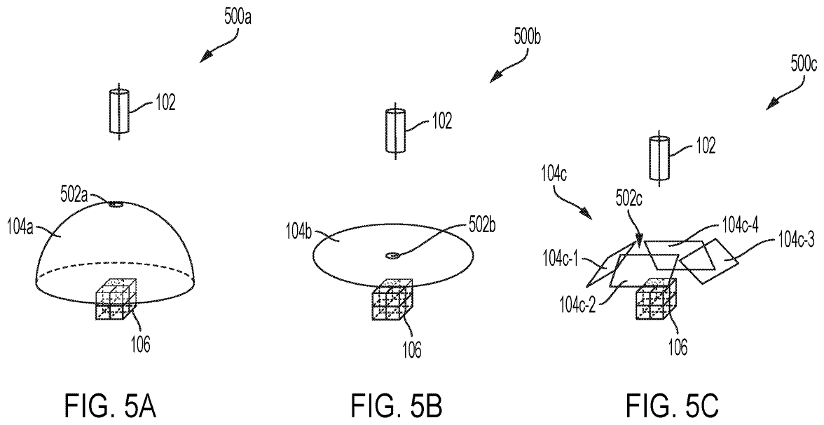

SEM systems provided herein may include detectors having various configurations. For example, detectors of SEM systems may be arranged with different shapes, with different positions relative to probes or samples, and/or with different orientations relative to probes or samples. FIGS. 5A-5C show a various exemplary embodiment of detectors of SEM systems.

FIG. 5A shows an SEM system 500a with a detector 104a, as well as a probe 102 and a sample 106. In FIG. 5A, detector 104a includes a hemisphere detection surface.

FIG. 5B shows an SEM system 500b with a detector 104b, as well as a probe 102 and a sample 106. In FIG. 5B, detector 104b includes a planar detection surface that is a circular detection surface.

FIG. 5C shows an SEM system 500c with a detector 104c, as well as a probe 102 and a sample 106. In FIG. 5C, detector 104c includes a plurality of planar detection surfaces 104c-1, 104c-2, 104c-3, and 104c-4. In FIG, 5C, the planar detection surfaces 104c-1, 104c-2, 104c-3, and 104c-4 are angled towards the sample 106 (and away from the probe 102 and its axis of electron emission) and are positioned in different quadrants above the sample 106 (and therefore also positioned in different quadrants relative to the probe 102 and its axis).

According to various embodiments, detectors of SEM systems may comprise one or more three-dimensional detection surfaces, and/or one or more planar detection surfaces. For example, detectors may include three-dimensional detection surfaces, such as a concave detection surface, a partial sphere detection surface, or a hemisphere detection surface.

In some embodiments, detectors may include planar detection surfaces, such as circular detection surfaces. In some embodiments, the planar detection surface may be a single planar detection surface of the detector. In other embodiments, the detector may comprise a plurality of planar detection surfaces.

Detection surfaces may also be arranged relative to the probe and/or sample position of the SEM system. For example, the detection surfaces may be arranged at different distances along the axis of the probe of the SEM system, where the probe axis is the axis along which the probe emits electrons. The detection surfaces may also be arranged at different distances along directions perpendicular to the probe axis. Further, the detection surfaces may be arranged at different angles relative to the probe axis and/or the sample position. For example, a detector may include three or more planar detection surfaces that are arranged around an axis of the probe, where the normals of the three or more planar detection surfaces are angled relative to the axis. FIG. 5C shows one such exemplary arrangement. In FIG. 5C, the detector 104c includes four planar detection surfaces 104c-1, 104c-2, 104c-3, and 104c-4. that are arranged around the axis in four different quadrants relative to the sample 106, with their normals facing the sample 106.

The detection surfaces may be arranged to gather sufficient data from electrons such that subvoxel features may be measured without necessarily capturing every single scattered electron. For example, the detection surfaces may be arranged in positions configured to capture a majority of or a statistically sufficient portion of the electrons scattered by the sample. For example, tests or simulations may be used to determine optimal positioning of the one or more detection surfaces, in order to ensure that a statistically sufficient portion of scattered electrons are captured. The statistically sufficient portion of electrons may correspond to an amount of scattered electrons sufficient for the SEM system to determine subvoxel features of the sample using the measured electron data. In various embodiments, detector size and position may be different based on desired performance or cost. For example, a bigger or more complexly shaped detector may cost more but capture more electrons and therefore provide more accurate measurements or require less model training. In other embodiments, a smaller or most simply shaped detection may cost less and capture fewer electrons, therefore requiring more model training in order to provide similar accuracy measurements of bigger or more complexly shaped detectors.

In various embodiments, a detector may include a gap. The gap may comprise an open space between the probe 102 and the sample. The probe may direct electrons through the gap, along its emission axis. In some embodiments, the gap may comprise a hole in a detection surface, though the gap may also include an open space between two or more different detection surfaces. In FIG. 5A, detector 104a comprises a gap 502a that is an opening in the hemisphere detection surface. In FIG. 5B, detector 104b comprises a gap 502b that is an opening in the planar, circular detection surface. As such, the detector 104b may form a donut shape. In FIG. 5C, detector 104c includes gap 502c which is an open space between the plurality of planar detection surfaces 104c-1, 104c-2, 104c-3, and 104c-4.

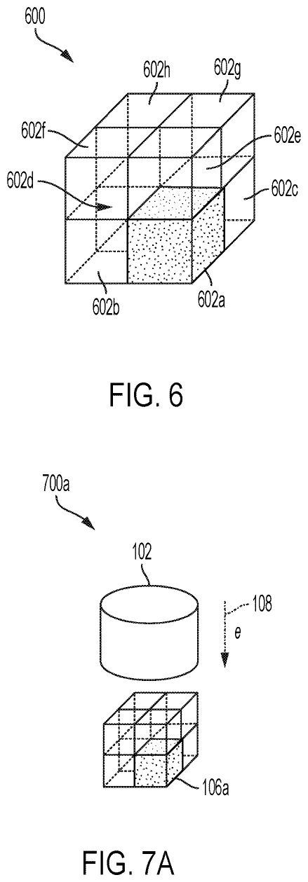

As described throughout the disclosure, SEM systems described herein may be configured to detect subvoxel features of samples. FIG. 6 shows an exemplary SEM system voxel and subvoxels thereof. FIG. 6 shows a sample comprising a voxel 600. According to some embodiments, voxel 600 may have a dimension that is substantially equal to the size of a probe of an SEM system, such as the size of probe 102. Accordingly, voxel 600 may represent a minimum resolution of a conventional SEM system that is incapable of measuring features smaller than the size of its probe.

A voxel 600 and subvoxel features thereof, such as illustrated in FIG. 6, may be measured by SEM systems described herein. According to some embodiments, voxel 600 comprises a plurality of subvoxels. In the illustrative embodiment of FIG. 6, voxel 600 comprises a plurality of eight subvoxels, arranged in a 2×2×2 cube. In other embodiments, voxel 600 may comprise a lesser or greater number of subvoxels, such as 27 subvoxels arranged in a 3×3×3 cube, 64 subvoxels arranged in a 4×4×4 cube, or subvoxels in other arrangements than cubes, such subvoxels arranged in hexagonal packing schemes or other features arranged in other packing schemes. According to aspects of the disclosure, SEM systems described herein may measure subvoxel features such as the subvoxels 602a-602f shown in FIG. 6 even though a probe of the SEM system may be larger than the subvoxels 602a-602f.

The plurality of subvoxels in FIG. 6 includes a first subvoxel 602a, a second subvoxel 602b, a third subvoxel 602c, a fourth subvoxel 602d, a fifth subvoxel 602e, a sixth subvoxel 602f, a seventh subvoxel 602g, and an eighth subvoxel 602h. The first subvoxel 602a is arranged in a front lower right position relative to the view of FIG. 6 and may be referred to as a 00000001 position subvoxel. The second subvoxel 602b is arranged in a front lower left position and may be referred to as a 00000010 position subvoxel. The third subvoxel 602c is arranged in a back lower right position and may be referred to as a 00000100 position subvoxel. The fourth subvoxel 602d is arranged in a back lower left position and may be referred to as a 00001000 position subvoxel. The fifth subvoxel 602e is arranged in a front upper right position and may be referred to as a 00010000 position subvoxel. The sixth subvoxel 602f is arranged in a front upper left position and may be referred to as a 00100000 position subvoxel. The seventh subvoxel 602g is arranged in a back upper right position and may be referred to as a 01000000 position subvoxel. The eighth subvoxel 602h is arranged in a back upper left position and may be referred to as a 10000000 position subvoxel.

According to various embodiments, a probe directs electrons towards a sample and the incoming beam of electrons interacts with atoms in the sample. When the electrons interact with atoms of the specimen, inelastic scattering and/or elastic scattering may occur. In an inelastic scattering event, an incoming electron may lose its energy, and may only slightly deviate from its original path. In an elastic scattering event, an incoming electron may experience larger changes to its travel path and may have little to no energy loss. According to various embodiments, in order to train a model for an SEM system (described in more detail below), electron scattering events, such as inelastic scattering and/or elastic scattering, may be simulated using Monte Carlo calculations in order to build a set of training data for an SEM system. The Monte Carlo calculations may be used to effectively predict the electron travel trajectory. According to aspects of the disclosures, refined physical models and accumulated experimental measurements may be used to perform advanced Monte Carlo simulations to calculate the training data. The training data may in turn be used by SEM systems or training systems to analyze interactions between electrons and samples and provide models for providing subvoxel information based on scattered election information. According to some embodiments, electron data from Monte Carlo simulations (or other electron data) may be used to generate a large amount of ground truth, which can be used to train a deep learning model (or other model). The model may be configured to classify patterns of electron data in order to reconstruct subvoxel features of samples. In some embodiments, a model generated using Monte Carlo simulation data may thereafter be refined using experimental data.

According to aspects of the disclosure, Monte Carlo simulations may be used to provide backscattered electron (BSE) energy and angular (or positional) distributions. According to merely one example, a sample may include a 5 nm gold cube embedded in epoxy resin cube with a size of 10 mm, with the epoxy including carbon, hydrogen, and oxygen. According to one embodiment, a probe may direct an incoming electron beam with an energy of E=1 kV, and the probe may be sized to provide a beam diameter of 10 nm that radiates perpendicularly towards a sample. As may be appreciated, the beam diameter of 10 nm is of equal size to the epoxy cube, and as such, conventional SEM systems may not be able to measure the smaller 5 nm gold cube within the epoxy.

In some embodiments, the sample (which, as described above, may be simulated) may scatter electrons. Each BSE may have an energy e, with e<=E, and may have a scattered direction defined by ψ and φ (e.g., as illustrated in FIG. 1A). As such, the data encoded by a BSE may be visualized as a single dot in a 3D space defined by ψ, φ, and e. In some embodiments, an SEM system or training system may obtain simulations of multiple electrons, in order to generate a plurality of dots in the 3D space, and may form an “electron cloud.” When measured by an SEM system, unique samples, made up of subvoxel features having varying sizes and materials, may each encode a different electron cloud. Each such electron cloud may have identifiable properties, including shape, density, distribution, among other properties. In some embodiments, detectors of various shapes may be used to capture the electron cloud of samples. As described in more detail above, the detectors may include hemisphere detectors, circular detectors, donut-shaped detector, or detectors of multiple planar surfaces, among other configurations.

One exemplary discussion of unique electron clouds follows. In the exemplary embodiment of a gold cube in epoxy, the high atomic number of the gold material has a feature size of 5 nm, which is smaller than the incoming electron probe size of 10 nm. When the gold cube is arranged in one particular position of the epoxy relative to probe, the sample imparts upon the scattered electrons a distinct pattern in the electron cloud. This distinct pattern of the electron cloud is different from the pattern generated by the sample when the gold cube is located in any other quadrant. As merely one example of differences between the electron data, FIGS. 7B, 8B, 9B, 10B, 11B, 12B, 13B, and 14B (discussed in more detail below) show that a centroid of the electron cloud may be formed in an area opposite the area in which the gold cube is arranged, due to the high reflectivity of gold associated with its high atomic number. This unique centroid may be used by an SEM system to determine that the sample includes a gold feature with a size of 5 nm, and may identify the respective subvoxel in which the gold feature is arranged within the voxel of the sample.

In various embodiments, probes such as probe 102 may be arranged having different angles relative to the sample. For example, in some embodiments, the probe may be arranged to provide the incoming electron beam substantially perpendicular or perpendicular relative to the sample, (e.g., with θ=0), though other angles may be used.

FIGS. 7A, 8A, 9A, 10A, 11A, 12A, 13A, and 14A show various exemplary samples for an SEM system. FIGS. 7B, 8B, 9B, 10B, 11B, 12B, 13B, and 14B show various exemplary data of a SEM system for the corresponding samples of FIGS. 7A, 8A, 9A, 10A, 11A, 12A, 13A, and 14A. In the illustrated embodiments, the samples may each correspond to an exemplary 10 nm epoxy block with a 5 nm gold (Au) subvoxel feature arranged at a different position within the epoxy block. By using the different data for each of the different samples, a SEM system may be able to determine subvoxel features of the epoxy block, such as by identifying the size and location of the gold block. FIGS. 7B, 8B, 9B, 10B, 11B, 12B, 13B, and 14B may represent data for a hemisphere detection surface. In various embodiments, the electron information, such as the data of FIGS. 7B, 8B, 9B, 10B, 11B, 12B, 13B, and 14B (which may be used as training data) may be generated by real-world experimental processes, using Monte Carlo simulations, or by other suitable methods.

FIG. 7A shows a first exemplary sample 106a for an SEM system 700a and FIG. 7B shows first exemplary data that may be gathered by the SEM system 700a for the sample 106a. SEM system 700a may be the SEM system 100 of FIG. 1A, and it includes a probe 102 configured to direct incoming probe electrons 108 at a sample 106a, and a detector (not illustrated) configured to detect electrons scattered by the sample 106a, in order to measure sample 106b. Sample 106a represents a voxel (such as voxel 600) with a subvoxel feature (e.g., the gold block described above) located at the position of the 00000001 position subvoxel, in the front lower right position relative to the view of the illustration (e.g., at the first subvoxel 602a of FIG. 6). As shown in FIG. 7A, the probe 102 is the size of the voxel of sample 106a. As shown in FIG. 7B, the SEM system 700a may obtain electron information 700b based on detecting electrons scattered by sample 106a. FIG. 7B may represent data with 7373 detected BSE, 7376 total BSE, and 50000 incoming electrons.

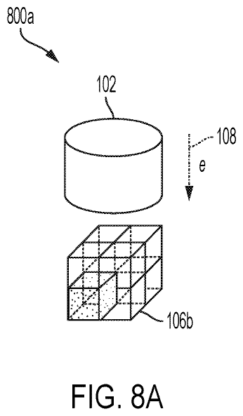

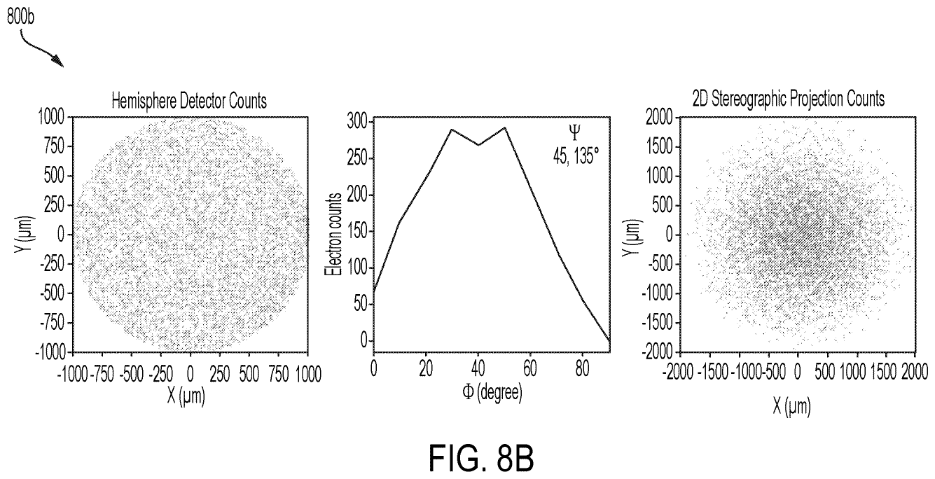

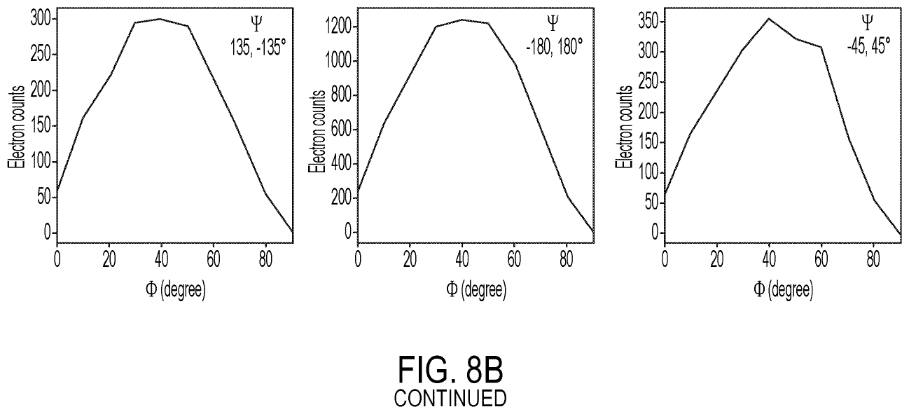

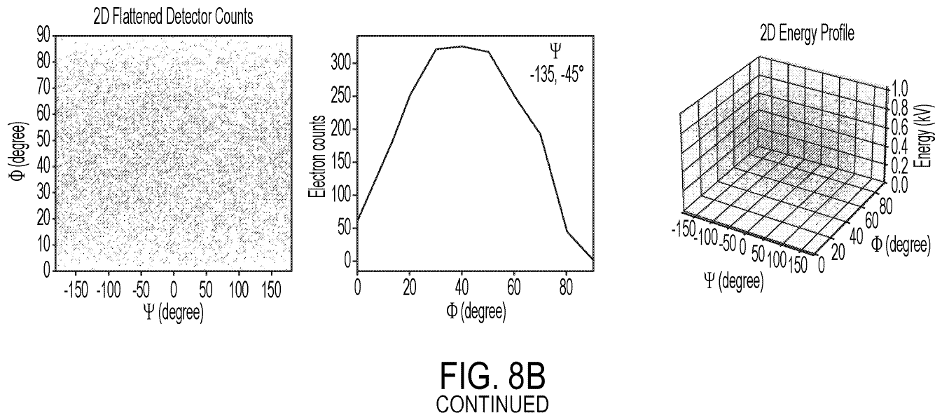

FIG. 8A shows a second exemplary sample 106b for an SEM system 800a and FIG. 8B shows second exemplary data that may be gathered by the SEM system 800a for the sample of FIG. 8A. SEM system 800a differs from SEM system 700a in that it is configured to measure sample 106b. Sample 106b represents a voxel (such as voxel 600) with a subvoxel feature located at the position of the 00000010 position subvoxel, in the front lower left position relative to the view of the illustration (e.g., at the second subvoxel 602b of FIG. 6). As shown in FIG. 8A, the probe 102 is the size of the voxel of sample 106b. As shown in FIG. 8B, the SEM system 800a may obtain electron information 800b based on detecting electrons scattered by sample 106b. FIG. 8B may represent data with 7262 detected BSE, 7264 total BSE, and 50000 incoming electrons.

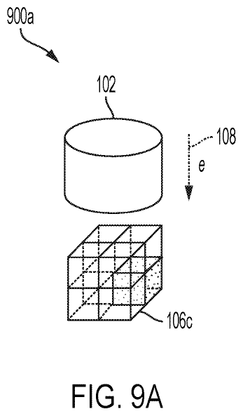

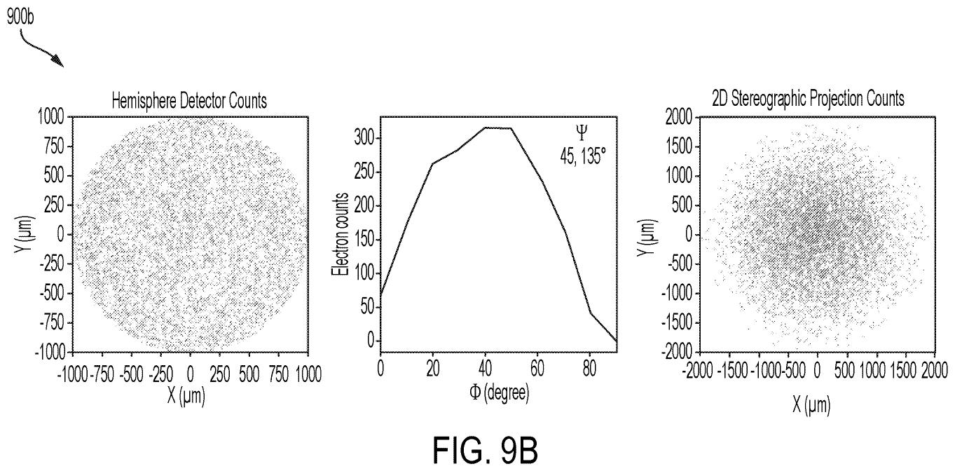

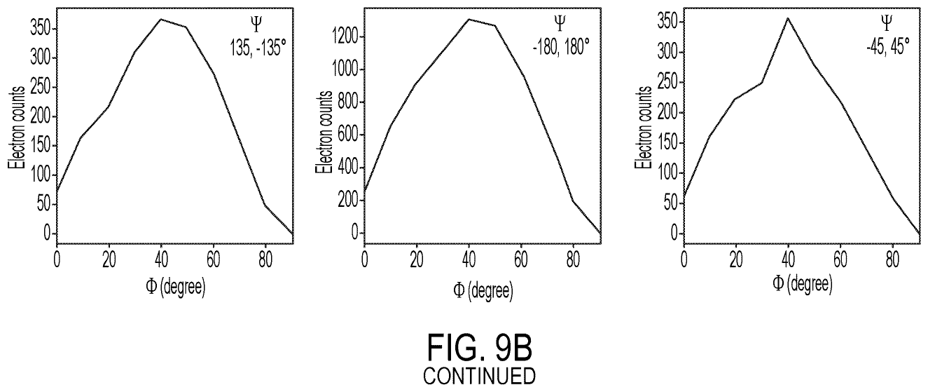

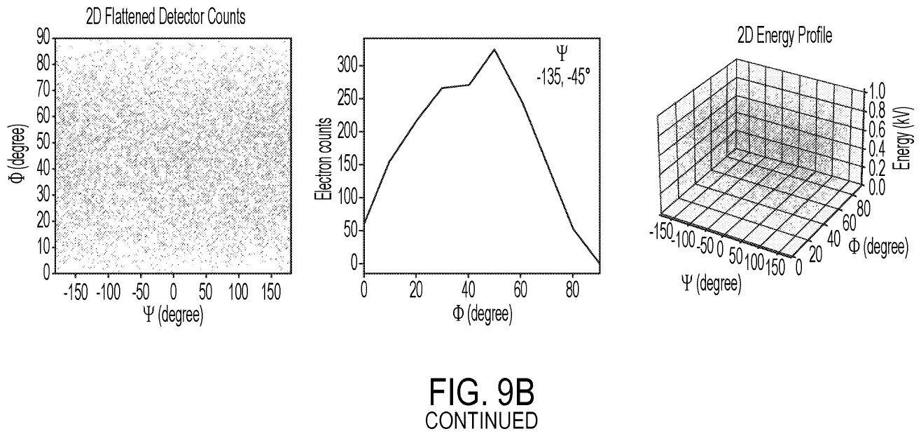

FIG. 9A shows a third exemplary sample 106c for an SEM system 900a and FIG. 9B shows third exemplary data that may be gathered by the SEM system 900a for the sample 106c of FIG. 9A. SEM system 900a differs from SEM system 700a in that it is configured to measure sample 106c. Sample 106c represents a voxel (such as voxel 600) with a subvoxel feature located at the position of the 00000100 position subvoxel, in the back lower right position relative to the view of the illustration (e.g., at the third subvoxel 602c of FIG. 6). As shown in FIG. 9A, the probe 102 is the size of the voxel of sample 106c. As shown in FIG. 9B, the SEM system 900a may obtain electron information 900b based on detecting electrons scattered by sample 106 c. FIG. 9B may represent data with 7258 detected BSE, 7259 total BSE, and 50000 incoming electrons.

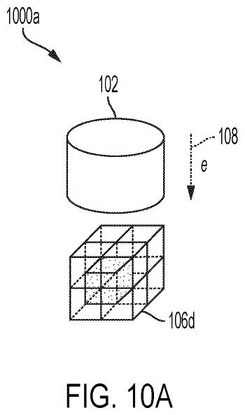

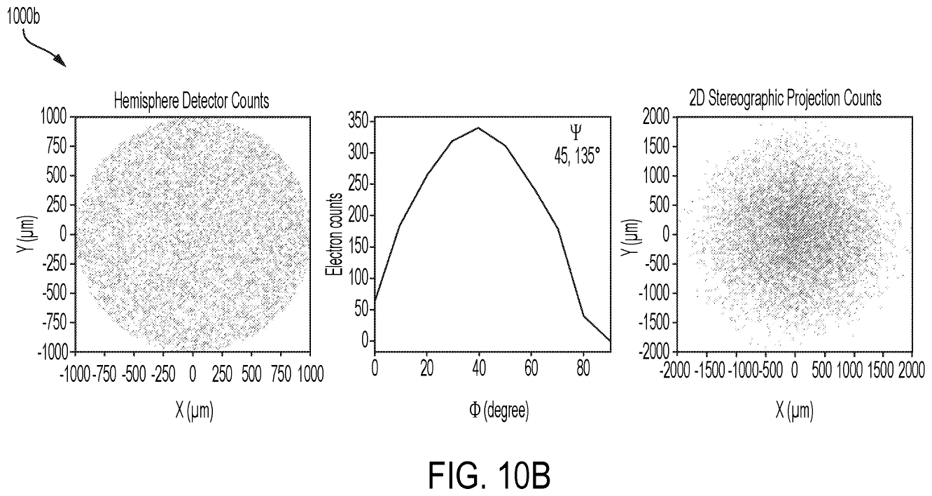

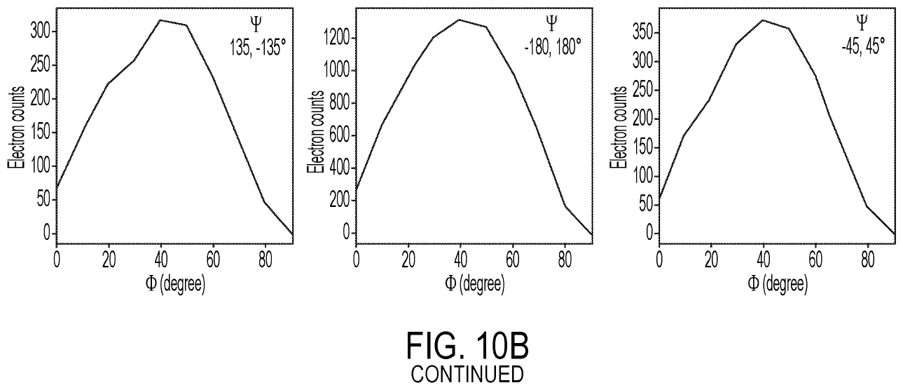

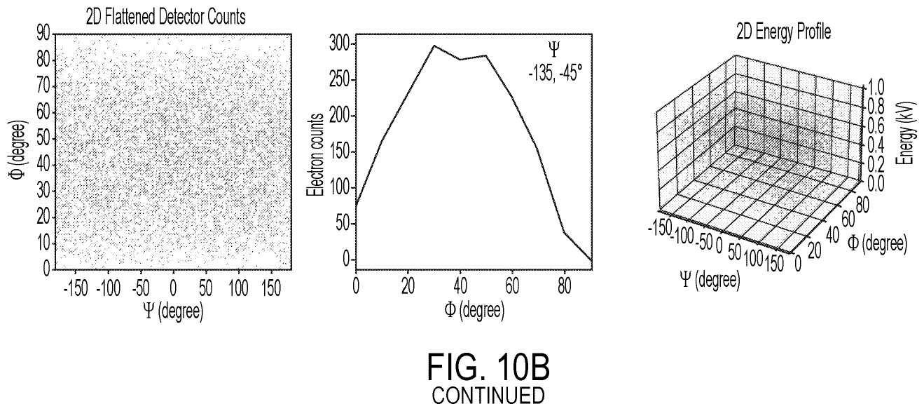

FIG. 10A shows a fourth exemplary sample 106d for an SEM system 1000a and FIG. 10B shows fourth exemplary data that may be gathered by the SEM system 1000a for the sample 106d of FIG. 10A. SEM system 1000a differs from SEM system 700a in that it is configured to measure sample 106d. Sample 106d represents a voxel (such as voxel 600) with a subvoxel feature located at the position of the 00001000 position subvoxel, in the back lower left position relative to the view of the illustration (e.g., at the fourth subvoxel 602d of FIG. 6). As shown in FIG. 10A, the probe 102 is the size of the voxel of sample 106d. As shown in FIG. 10B, the SEM system 1000a may obtain electron information 1000b based on detecting electrons scattered by sample 106d. FIG. 10B may represent data with 7402 detected BSE, 7405 total BSE, and 50000 incoming electrons.

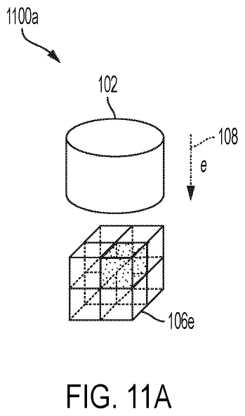

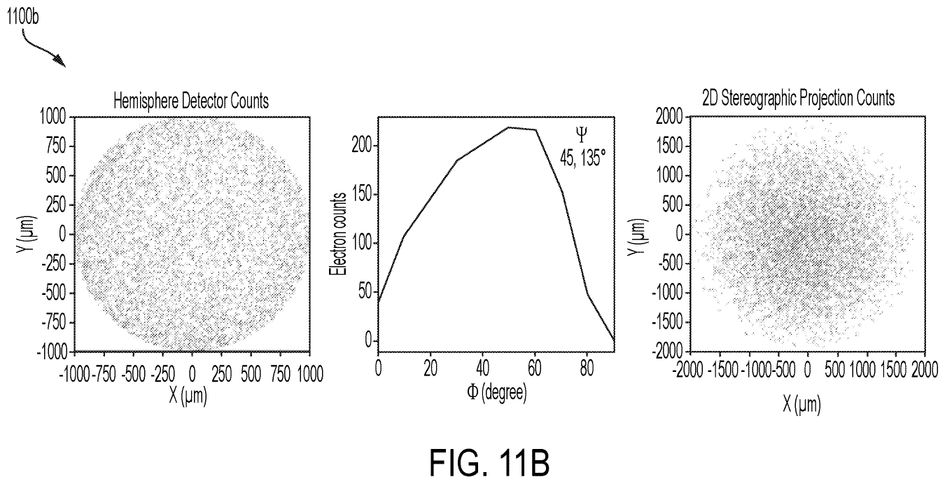

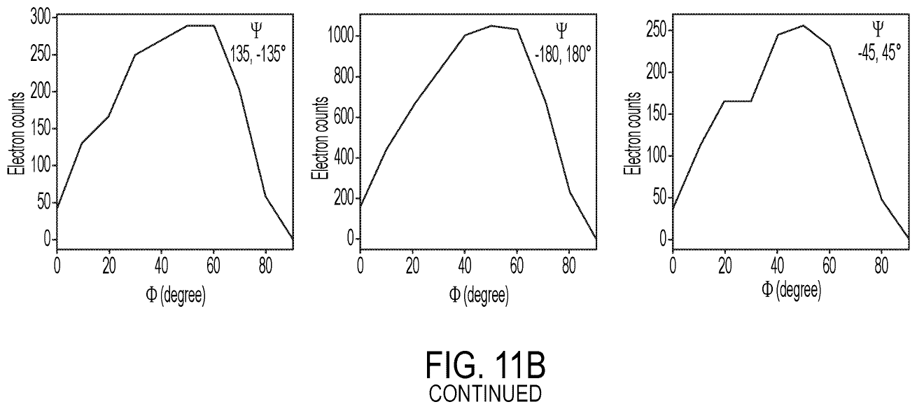

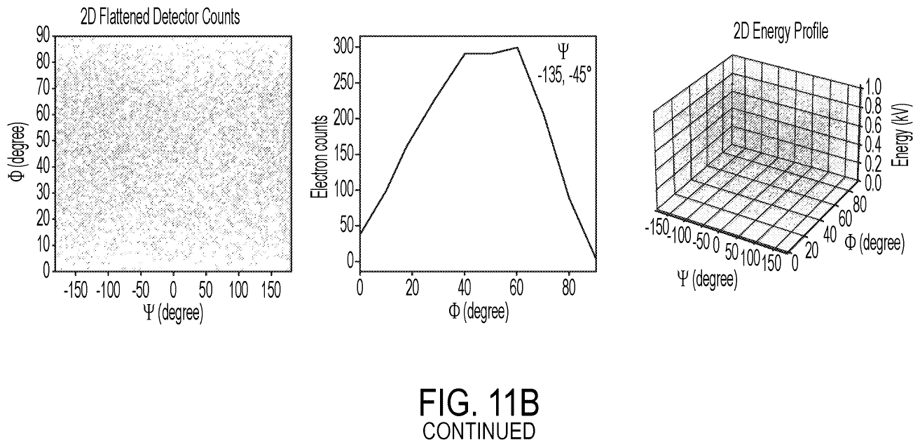

FIG. 11A shows a fifth exemplary sample 106e for an SEM system 1100a and FIG. 11B shows fifth exemplary data that may be gathered by the SEM system 1100a for the sample 106e of FIG. 11A. SEM system 1100a differs from SEM system 700a in that it is configured to measure sample 106e. Sample 106e represents a voxel (such as voxel 600) with a subvoxel feature located at the position of the 0001000 position subvoxel, in the front upper right position relative to the view of the illustration (e.g., at the fifth subvoxel 602e of FIG. 6). As shown in FIG. 11A, the probe 102 is the size of the voxel of sample 106e. As shown in FIG. 11B, the SEM system 1100a may obtain electron information 1100b based on detecting electrons scattered by sample 106 e. FIG. 11B may represent data with 6096 detected BSE, 6098 total BSE, and 50000 incoming electrons.

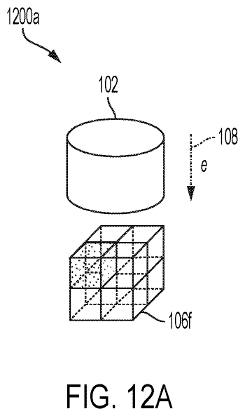

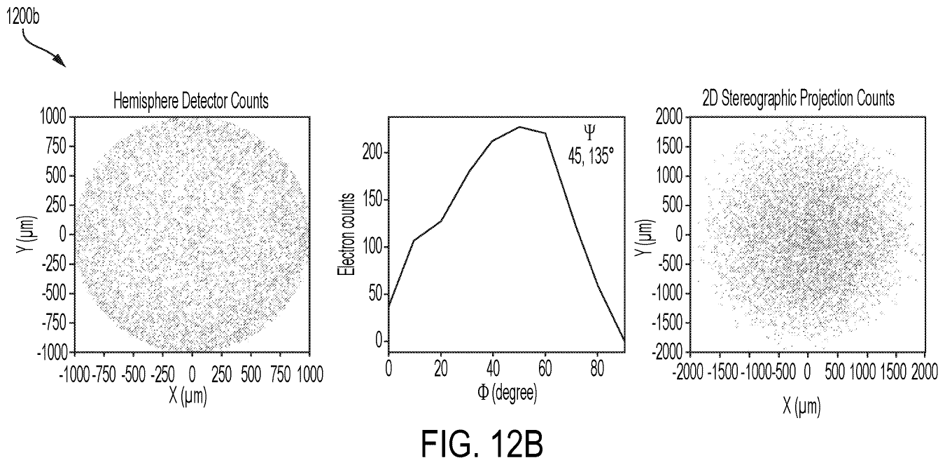

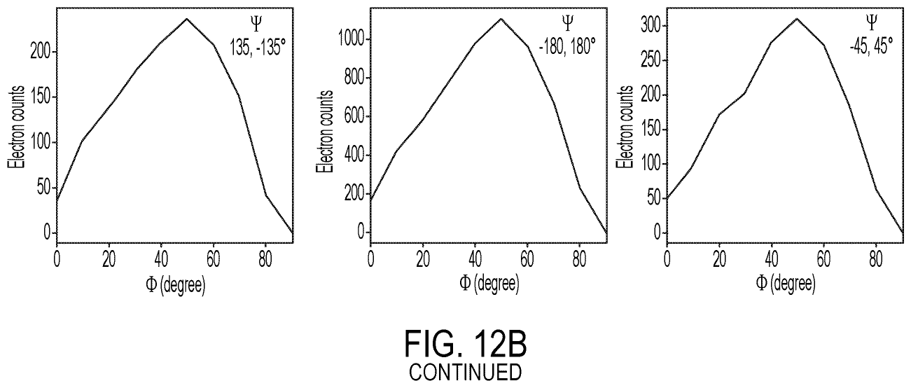

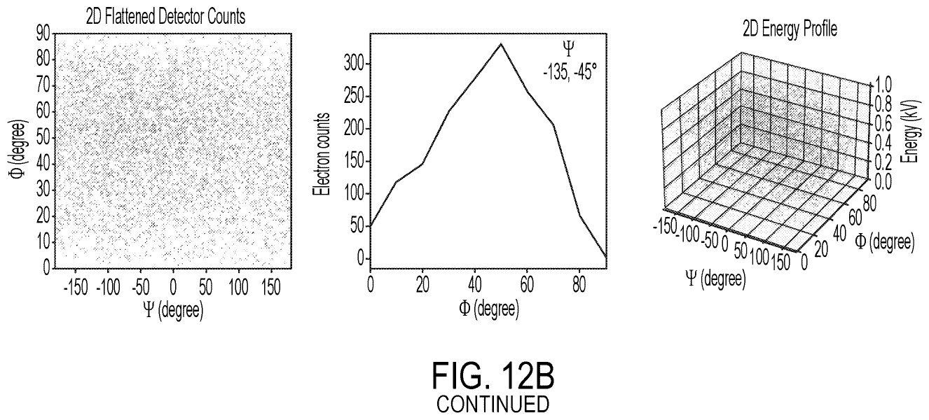

FIG. 12A shows a sixth exemplary sample 106f for an SEM system 1200a and FIG. 12B shows sixth exemplary data that may be gathered by the SEM system 1200a for the sample 106f of FIG. 12A. SEM system 1200a differs from SEM system 700a in that it is configured to measure sample 106f. Sample 106f represents a voxel (such as voxel 600) with a subvoxel feature located at the position of the 0010000 position subvoxel, in the front upper left position relative to the view of the illustration (e.g., at the sixth subvoxel 602f of FIG. 6). As shown in FIG. 12A, the probe 102 is the size of the voxel of sample 106f. As shown in FIG. 12B, the SEM system 1200a may obtain electron information 1200b based on detecting electrons scattered by sample 106 f. FIG. 12B may represent data with 5864 detected BSE, 5867 total BSE, and 50000 incoming electrons.

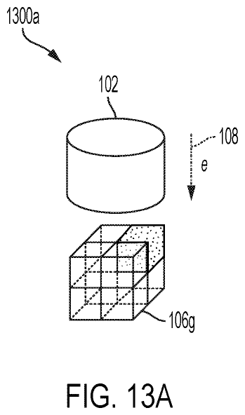

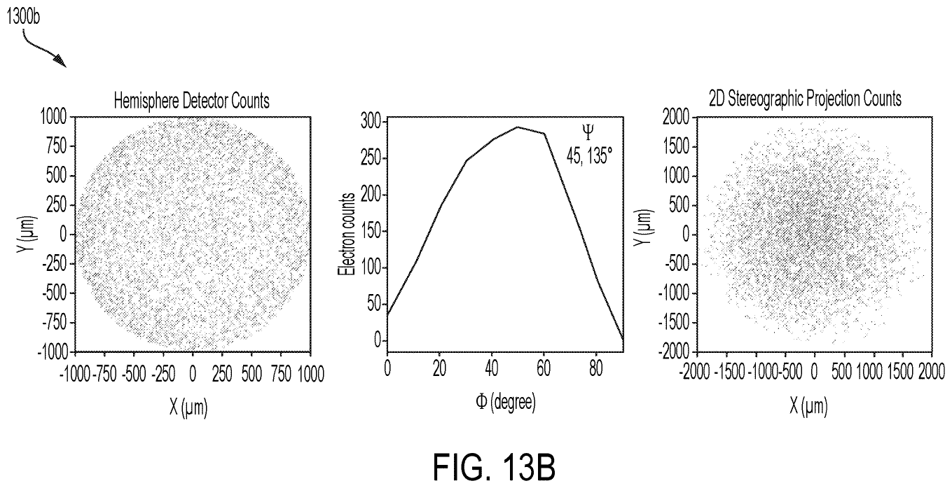

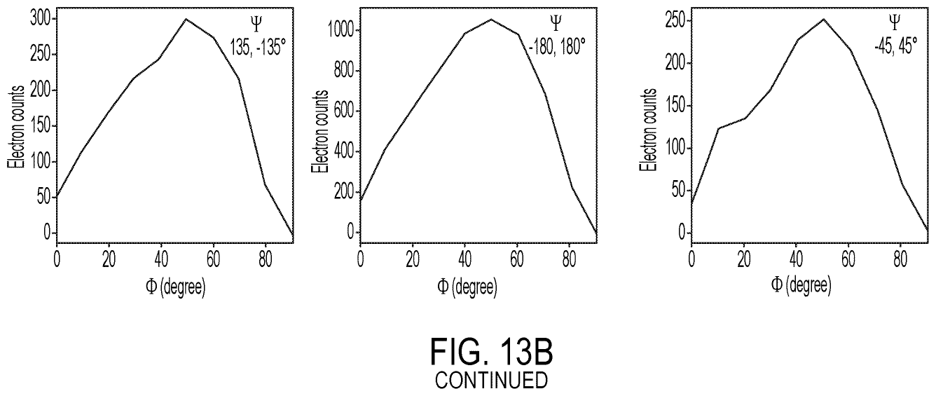

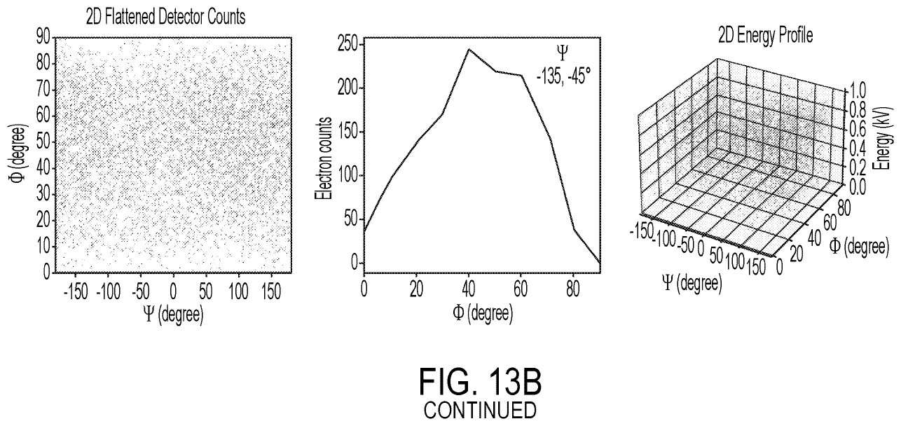

FIG. 13A shows a seventh exemplary sample 106g for an SEM system 1300a and FIG. 13B shows seventh exemplary data that may be gathered by the SEM system 1300a for the sample 106g of FIG. 13A. SEM system 1300a differs from SEM system 700a in that it is configured to measure sample 106g. Sample 106g represents a voxel (such as voxel 600) with a subvoxel feature located at the position of the 0100000 position subvoxel, in the back upper right position relative to the view of the illustration (e.g., at the seventh subvoxel 602g of FIG. 6). As shown in FIG. 13A, the probe 102 is the size of the voxel of sample 106g. As shown in FIG. 13B, the SEM system 1300a may obtain electron information 1300b based on detecting electrons scattered by sample 106 g. FIG. 13B may represent data with 5919 detected BSE, 5924 total BSE, and 50000 incoming electrons.

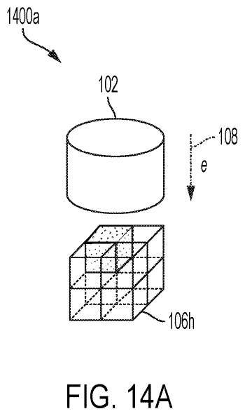

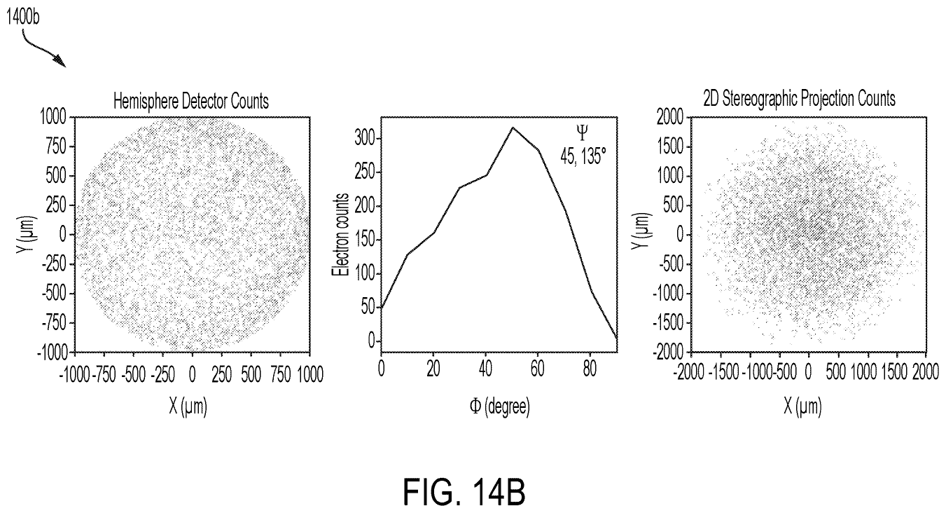

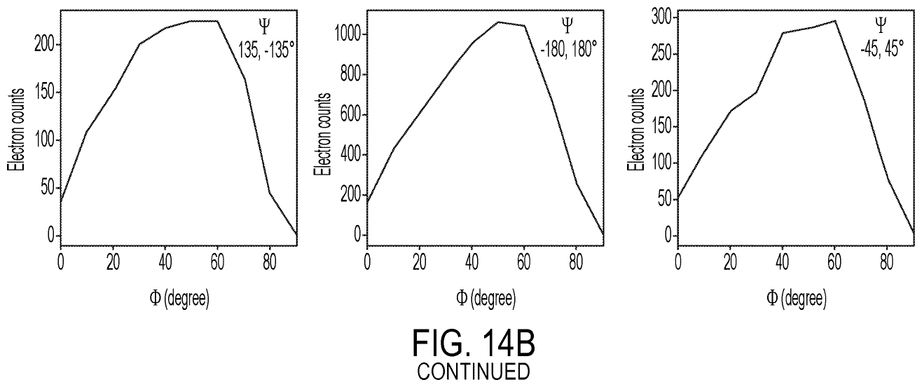

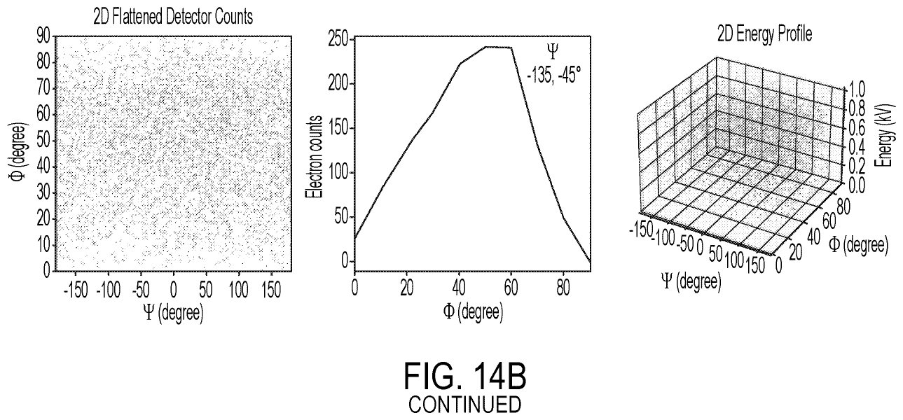

FIG. 14A shows an eighth exemplary sample 106h for an SEM system 1400a and FIG. 14B shows eight exemplary data that may be gathered by the SEM system 1400a for the sample 106h of FIG. 14A. SEM system 1400a differs from SEM system 700a in that it is configured to measure sample 106h. Sample 106h represents a voxel (such as voxel 600) with a subvoxel feature located at the position of the 1000000 position subvoxel, in the back upper left position relative to the view of the illustration (e.g., at the eighth subvoxel 602h of FIG. 6). As shown in FIG. 14A, the probe 102 is the size of the voxel of sample 106h. As shown in FIG. 14B, the SEM system 1400a may obtain electron information 1400b based on detecting electrons scattered by sample 106 h. FIG. 14B may represent data with 5970 detected BSE, 5972 total BSE, and 50000 incoming electrons.

Electron information collected by an SEM system for electrons scattered by a sample may comprise various types of electron information. As shown in FIGS. 7B, 8B, 9B, 10B, 11B, 12B, 13B, and 14B, electron information 700b, 800b, 900b, 1000b, 1100b, 1200b, 1300b, and 1400b include various types of electron information.

Electron information may be collected having multi-dimensional electron profile information. Multi-dimensional electron profile information may in turn be collected at a set of points arranged in multiple spatial dimensions. For example, electron profile information may be multidimensional (e.g., such as two-dimensional) in that it includes both an electron count along a first profile dimension and an electron energy along a second profile dimension.

Electron profile information may also be collected in multiple spatial dimensions. The multiple spatial dimensions may be for example, on a two-dimensional surface, or on a three-dimensional surface. The surface may comprise a plurality of pixels. Each pixel on a two-dimensional surface may have two spatial coordinates associated with which it is associated. Each pixel on a three-dimensional surface therefore have three spatial coordinates associated with which it is associated.

Each pixel may collect electron information in two dimensions, e.g., electron count and electron energy, as described above. Therefore, in total, each pixel of a two-dimensional surface may have four pieces of associated information (in each sampling period): two spatial coordinates, electron count, and electron energy. In total, each pixel of a three-dimensional surface may have five pieces of associated information (in each sampling period): three spatial coordinates, electron count, and electron energy.

At the first row, first column, the electron information shows a first plot of hemisphere detector (which may have a radius of about 800-1200 μm, or a radius of about 1000 μm) counts, with electrons plotted as points, and with a horizontal axis for X position of the hemisphere detector pixel in um and a vertical axis for Y position of the hemisphere detector pixel in μm. In some embodiments, the center of the sample top surface may correspond to a location at the origin (e.g., X=0 μm, Y=0 μm, and Z=0 μm). The plot at the first row, first column may correspond to a parallel projection of the electron profile (from the hemisphere detector) along the Z axis onto the X-Y plane at Z=0 μm. At the first row, second column, the electron information shows a second plot at y between 45° and 135° (e.g., a “north” quadrant) with electron counts plotted on the vertical axis, and with a horizontal axis for φ in degrees. At the first row, third column, the electron information shows a third plot with 2D stereographic projection counts, with electrons plotted as points, and with a horizontal axis for X position in μm and a vertical axis for Y position in um. The third plot at the first row, third column may correspond to a projection of the electron profile from the point X=0 μm, Y=0 μm, and Z=1000 μm (1000 μm below the origin) on to the X-Y plane at Z=−1000 μm (the top of the hemisphere detector, 1000 μm above the origin).

While the exemplary detector may have a size of about 1000 μm as discussed above, detectors in various embodiments may have other dimensions. For example, detectors may have a size ranging from about a few millimeters to several centimeters. Detectors may be sized based on sample size or based on a desired sample space size.

At the second row, first column, the electron information shows a second plot at y between 135° and −135 ° (e.g., a “west” quadrant) with electron counts plotted on the vertical axis, and with a horizontal axis for φ in degrees. At the second row, second column, the electron information shows a second plot at ψ between −180° and 180° (e.g., a sum of all four quadrants) with electron counts plotted on the vertical axis, and with a horizontal axis for φ in degrees. At the second row, third column, the electron information shows a second plot at y between −45° and 45° (e.g., a “east” quadrant) with electron counts plotted on the vertical axis, and with a horizontal axis for φ in degrees.

At the third row, first column, the electron information shows a seventh plot with 2D flattened detector counts, with electrons plotted as points, and with a horizontal axis for ψ in degrees and a vertical axis for φ in degrees. At the third row, second column, the electron information shows a second plot at ψ between −135° and −45° (e.g., a “south” quadrant) with electron counts plotted on the vertical axis, and with a horizontal axis for φ in degrees. At the third row, third column, the electron information shows a ninth plot with 2D energy profile, with energy in kV on the vertical axis, and with horizonal axes for ψ and φ in degrees.

According to various embodiments, electron information such as electron information 700b, 800b, 900b, 1000b, 1100b, 1200b, 1300b, and 1400b (or other electron information) may be used to determine subvoxel information of the samples 106a-106h. For example, an SEM system may process the electron information and determine that the electron information corresponds to a subvoxel feature being arranged at a particular location within a voxel. As can be observed from the electron information 700b, 800b, 900b, 1000b, 1100b, 1200b, 1300b, and 1400b, the electron scattered by the various samples 106a-106h are encoded different information depending on the different subvoxel features of the sample (for example, a differing position of a gold block in the epoxy block). E.g., locations of electron counts can be observed to vary throughout electron information 700b, 800b, 900b, 1000b, 1100b, 1200b, 1300b, and 1400b, with different regions having greater densities for different samples, with angular plots having different shapes and peaks at different locations, and with electron energy varying by sample. SEM systems described herein may exploit the different information encoded in the electrons for different samples in order to determine subvoxel features of the samples. In some embodiments, SEM systems may identify subvoxel features only using angular (or positional) electron information, without using electron energy information, thereby reducing detector complexity as the detector does not need to measure electron energy.

An SEM system may process the electron information as training data for generating a trained statistical model, as described throughout the disclosure. In some embodiments, SEM systems may include a model. The model may be configured to receive, as input, detected electron information based on electron scattered by a sample, and provide, as output, subvoxel information of the sample. In some embodiments, the model may comprise a statistical model trained on training data for known or annotated subvoxel information.

Models described herein may be trained using supervised machine learning. Supervised machine learning may include providing labeled training data to a classifier and penalizing or rewarding the classifier depending on whether the classifier correctly classifies the training data. For example, training a classifier to classify images of objects labeled as red, blue, or green may include rewarding the classifier for correctly classifying a green-labeled image of grass as green, and penalizing the classifier for incorrectly classifying a red-labeled image of a firetruck as blue. Thus, the classifier may properly classify future image inputs and infer whether to classify the images as red, blue or green. Accordingly input data may comprise labels indicating that the data is known to have similar characteristics, and/or different characteristics, in order to emphasize and/or de-emphasize the similar and/or different characteristics during training. During training of a model, weights and/or biases of the model may be adjusted to emphasize recognition of the particular characteristics of the training data. Supervised learning techniques may be useful for sorting new data into known categories, as in the image example.

Models described herein may also be trained using unsupervised machine leaning. Unsupervised machine learning may include providing unlabeled training data to an encoder which the encoder may sort into self-similar groups. For example, the same images provided to the classifier above may be provided to an encoder, which may map the images into a continuous space. In this example, the encoder may form clusters of similar images based on various perceived characteristics of the images, such as the color of the object in each image. However, unlike training the classifier, the encoder may take into account other characteristics of the input data, such as the shape of the objects in the images, and the encoder is not penalized for doing so in the manner described for the classifier. Accordingly, such encoders may be configured to group future inputs based on characteristics encountered during training. In some embodiments, models described herein may be trained using machine learning techniques that combine aspects of unsupervised and supervised machine learning.

In one such embodiment, a trained statistical model such as a neural network, or other appropriate statistical model, may be trained to output subvoxel information using the electron information described herein as input to the trained statistical model. In one embodiment, the electron information, such as some or all of the electron information from the plots described with respect to FIGS. 7B, 8B, 9B, 10B, 11B, 12B, 13B, and 14B (or other electron information), along with information identifying known subvoxel information of samples 106a-106h is input as training data into a statistical model in a machine learning module. Once these inputs have been received, the machine learning module may generate a trained statistical model using the training data. The resulting output from the machine learning module may correspond to a subvoxel information model, which is a trained statistical model of a subvoxel information as a function of some or all of the types of electron information described with respect to FIGS. 7B, 8B, 9B, 10B, 11B, 12B, 13B, and 14B. The trained statistical model may also be stored in an appropriate non-transitory computer readable medium for subsequent use as detailed further below.

It should be understood that the trained statistical models disclosed herein may be generated using any appropriate statistical model. For example, a machine learning module may correspond to any appropriate fitting method capable of generating the desired trained statistical models. It should also be understood that the above methods may be combined with any appropriate type of fitting approximation to provide a desired combination of model accuracy versus computational expense.

In general, a statistical model comprises a functional component designed and/or trained to analyze new inputs based on probabilistic patterns observed in prior training inputs. In this sense, statistical models differ from “rule-based” models, which typically apply hard-coded deterministic rules to map from inputs having particular characteristics to particular outputs. By contrast, a statistical model may operate to determine a particular output for an input with particular characteristics by considering how often (e.g., with what probability) training inputs with those same characteristics (or similar characteristics) were associated with that particular output in the statistical model's training data. To supply the probabilistic data that allows a statistical model to extrapolate from the tendency of particular input characteristics to be associated with particular outputs in past examples, statistical models are typically trained (or “built”) on large training corpuses with great numbers of example inputs. Typically, the example inputs may be labeled with the known outputs with which they should be associated, usually by a human labeler with expert knowledge of the domain. Characteristics of interest (known as “features”) are identified (“extracted”) from the inputs, and the statistical model learns the probabilities with which different features are associated with different outputs, based on how often training inputs with those features are associated with those outputs. When the same features are extracted from a new input (e.g., an input that has not been labeled with a known output by a human), the statistical model can then use the learned probabilities for the extracted features (as learned from the training data) to determine which output is most likely correct for the new input. Illustrative implementations of a fact extraction component using one or more statistical models are described further below.

The terms “program” or “software” are used herein in a generic sense to refer to any type of computer code or set of processor-executable instructions that can be employed to program a computer or other processor to implement various aspects of embodiments as discussed above. Additionally, it should be appreciated that according to one aspect, one or more computer programs that when executed perform methods of the disclosure provided herein need not reside on a single computer or processor but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Also, data structures may be stored in one or more non-transitory computer-readable storage media in any suitable form. For simplicity of illustration, data structures may be shown to have fields that are related through location in the data structure. Such relationships may likewise be achieved by assigning storage for the fields with locations in a non-transitory computer-readable medium that convey relationship between the fields. However, any suitable mechanism may be used to establish relationships among information in fields of a data structure, including through the use of pointers, tags or other mechanisms that establish relationships among data elements.

Also, various inventive concepts may be embodied as one or more processes, of which examples (for example, FIG. 4) are provided. The acts performed as part of each process may be ordered in any suitable way. Accordingly, embodiments may be constructed in which acts are performed in an order different than illustrated, which may include performing some acts simultaneously, even though shown as sequential acts in illustrative embodiments.

FIG. 4 shows an exemplary process flow 400 of a method of determining subvoxel information for use with a scanning electron microscopy (SEM) system. Process flow 400 includes act 402, act 404, and act 406. At act 402, the process flow 400 may include obtaining an energy of incoming probe electrons and a direction of the incoming probe electrons. At act 404, the process flow 400 may obtaining a two-dimensional energy profile map of detected electrons. At act 406, the process flow 400 may include determining subvoxel information of a sample using the energy of incoming probe electrons, the direction of the incoming probe electrons, and the two-dimensional energy profile map of the detected electrons.

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately,” “about,” and “substantially” may be used to mean within ±20% of a target value in some embodiments, within ±10% of a target value in some embodiments, within ±5% of a target value in some embodiments, within ±2% of a target value in some embodiments. The terms “approximately,” “about,” and “substantially” may include the target value.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

What is claimed is:

1. An apparatus, comprising:
a scanning electron microscopy (SEM) system, comprising:
a probe configured to direct incoming probe electrons at a sample, the incoming probe electrons having an energy and a direction; and
a detector configured to detect electrons scattered by the sample and generate a two-dimensional energy profile map of the detected electrons.

2. The apparatus of claim 1, wherein the two-dimensional energy profile map of the detected electrons comprises:
a map having at least two spatial dimensions; and
for a plurality of points in the map, a two-dimensional energy profile comprising:
an electron count along a first profile dimension; and
an electron energy along a second profile dimension.

3. The apparatus of claim 1, wherein the detector is further configured to:
detect energy and direction of the detected electrons; and
generate the two-dimensional energy profile map of the detected electrons based on the detected energy and direction of the detected electrons.

4. The apparatus of claim 1, wherein the SEM system is further configured to determine subvoxel information of the sample using the energy of the incoming probe electrons, the direction of the incoming probe electrons, and the two-dimensional energy profile map of the detected electrons.

5. The apparatus of claim 4, wherein the subvoxel information comprises features of the sample that are smaller than a size of the probe.

6. The apparatus of claim 1, wherein the SEM system is further configured to determine three-dimensional subvoxel information of the sample.

7. The apparatus of claim 1, wherein the SEM system is a focused ion beam scanning electron microscopy (FIB-SEM) system comprising a focused ion beam (FIB) emitter configured to direct a FIB at the sample and separate layers of the sample using the FIB.

8. The apparatus of claim 7, wherein the FIB-SEM system is further configured to:
for a first layer of the sample having a sample layer thickness, obtain energy and direction of incoming probe electrons and generate a two-dimensional energy profile map of detected electrons;
using the FIB, separate the first layer of the sample from a second layer of the sample;
for the second layer of the sample, obtain energy and direction of incoming probe electrons and generate a two-dimensional energy profile map of detected electrons; and
generate three-dimensional subvoxel volume information of the sample, the three-dimensional subvoxel volume information having a volume information thickness greater than the sample layer thickness.

9. The apparatus of claim 8, wherein the detector is further configured to:
for each of the first layer and the second layer:
detect the energy and direction of the detected electrons; and
generate the two-dimensional energy profile map of the detected electrons based on the detected energy and direction of the detected electrons.

10. The apparatus of claim 1, wherein the detector comprises a three-dimensional detection surface.

11. The apparatus of claim 1, wherein the detector comprises a concave detection surface.

12. The apparatus of claim 1, wherein the detector comprises a partial sphere detection surface.

13. The apparatus of claim 1, wherein the detector comprises a hemisphere detection surface.

14. The apparatus of claim 1, wherein the detector comprises at least one planar detection surface.

15. The apparatus of claim 1, wherein the detector comprises a single planar detection surface.

16. The apparatus of claim 1, wherein the detector comprises a circular detection surface.

17. The apparatus of claim 1, wherein the detector comprises a plurality of planar detection surfaces.

18. The apparatus of claim 1, wherein the detector comprises three or more planar detection surfaces, wherein:
the three or more planar detection surfaces are arranged around an axis of the probe;
normals of the three or more planar detection surfaces are angled relative to the axis.

19. The apparatus of claim 18, wherein the three or more planar detection surfaces comprises four planar detection surfaces arranged in respective quadrants around the axis.

20. The apparatus of any of claims 10-19 wherein:
the detector further comprises a gap; and
the probe is configured to direct incoming probe electrons at the sample through the gap.

21. The apparatus of any of claims 10-19, wherein:
a detection surface of the detector comprises an opening; and
the probe is configured to direct incoming probe electrons at the sample through the opening.

22. A method of determining subvoxel information for use with a scanning electron microscopy (SEM) system, the method comprising:
obtaining an energy of incoming probe electrons and a direction of the incoming probe electrons;
obtaining a two-dimensional energy profile map of detected electrons; and
determining subvoxel information of a sample using the energy of incoming probe electrons, the direction of the incoming probe electrons, and the two-dimensional energy profile map of the detected electrons.

23. The method of claim 22, wherein obtaining the two-dimensional energy profile map of the detected electrons comprises:
obtaining a map having at least two spatial dimensions; and
for a plurality of points in the map, obtaining a two-dimensional energy profile comprising:
an electron count along a first profile dimension; and
an electron energy along a second profile dimension.

24. The method of claim 22, further comprising:
detecting energy and direction of the detected electrons; and
generating the two-dimensional energy profile map of the detected electrons based on the detected energy and direction of the detected electrons.

25. The method of claim 22, further comprising determining subvoxel information of the sample using the energy of the incoming probe electrons, the direction of the incoming probe electrons, and the two-dimensional energy profile map of the detected electrons.

26. The method of claim 25, wherein the subvoxel information comprises features of the sample that are smaller than a size of a probe of the SEM system.

27. The method of claim 22, further comprising determining three-dimensional subvoxel information of the sample.

28. The method of claim 22, further comprising separating layers of the sample.

29. The method of claim 28, further comprising:
for a first layer of the sample having a sample layer thickness, obtaining energy and direction of incoming probe electrons and generating a two-dimensional energy profile map of detected electrons;
separating the first layer of the sample from a second layer of the sample;
for the second layer of the sample, obtaining energy and direction of incoming probe electrons and generating a two-dimensional energy profile map of detected electrons; and
generating three-dimensional subvoxel volume information of the sample, the three-dimensional subvoxel volume information having a volume information thickness greater than the sample layer thickness.

30. The method of claim 29, further comprising:
for each of the first layer and the second layer:
detecting the energy and direction of the detected electrons; and
generating the two-dimensional energy profile map of the detected electrons based on the detected energy and direction of the detected electrons.

31. At least one non-transitory computer-readable storage medium having instructions encoded thereon that, when executed by at least one processor, cause the at least one processor to perform a method of determining subvoxel information for use with a scanning electron microscopy (SEM) system, the method comprising:
obtaining an energy of incoming probe electrons and a direction of the incoming probe electrons;
obtaining a two-dimensional energy profile map of detected electrons; and
determining subvoxel information of a sample using the energy of the incoming probe electrons, the direction of the incoming probe electrons, and the two-dimensional energy profile map of the detected electrons.

32. The at least one non-transitory computer-readable storage medium of claim 31, wherein obtaining the two-dimensional energy profile map of the detected electrons comprises:
obtaining a map having at least two spatial dimensions; and
for a plurality of points in the map, obtaining a two-dimensional energy profile comprising:
an electron count along a first profile dimension; and
an electron energy along a second profile dimension.

33. The at least one non-transitory computer-readable storage medium of claim 31, wherein the method further comprises:
detecting energy and direction of the detected electrons; and
generating the two-dimensional energy profile map of the detected electrons based on the detected energy and direction of the detected electrons.

34. The at least one non-transitory computer-readable storage medium of claim 31, wherein the method further comprises determining subvoxel information of the sample using the energy of the incoming probe electrons, the direction of the incoming probe electrons, and the two-dimensional energy profile map of the detected electrons.

35. The at least one non-transitory computer-readable storage medium of claim 34, wherein the subvoxel information comprises features of the sample that are smaller than a size of a probe of the SEM system.

36. The at least one non-transitory computer-readable storage medium of claim 31, wherein the method further comprises determining three-dimensional subvoxel information of the sample.

37. The at least one non-transitory computer-readable storage medium of claim 31, wherein the method further comprises separating layers of the sample.

38. The at least one non-transitory computer-readable storage medium of claim 37, wherein the method further comprises:
For a first layer of the sample having a sample layer thickness, obtaining energy and direction of incoming probe electrons and generating a two-dimensional energy profile map of detected electrons;
separating the first layer of the sample from a second layer of the sample;
for the second layer of the sample, obtaining energy and direction of incoming probe electrons and generating a two-dimensional energy profile map of detected electrons; and
generating three-dimensional subvoxel volume information of the sample, the three-dimensional subvoxel volume information having a volume information thickness greater than the sample layer thickness.

39. The at least one non-transitory computer-readable storage medium of claim 38, wherein the method further comprises:
for each of the first layer and the second layer:
detecting the energy and direction of the detected electrons; and
generating the two-dimensional energy profile map of the detected electrons based on the detected energy and direction of the detected electrons.
